(19) United States
(12) Patent Application Publication
(10) Pub. No.: US 2006/0279930 A1
(43) Pub. Date: Dec. 14, 2006

(54) Cooling apparatus of liquid-cooling type

(76) Inventors: Yukihiko Hata, Hamura-shi (JP); Kentaro Tomioka, Sayama-shi (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/473,561

(22) Filed: Jun. 22, 2006

Related U.S. Application Data
(63) Continuation of application No. PCT/JP04/18747, filed on Dec. 15, 2004.

(30) Foreign Application Priority Data
Dec. 26, 2003 (JP) 2003-433931

(51) Int. Cl. H05K 7/20

(52) U.S. Cl. 361/697; 361/698

(57) ABSTRACT

A cooling apparatus comprises an outlet port through which cooling air is applied in a radial direction, a plurality of heat radiating fins which are arranged at intervals and which surround the outlet port, and first to third paths in which liquid coolant flows. The first path extends in the direction the heat radiating fins are arranged and is thermally connected to a second edge of each heat radiating fin. The second path extends in the direction the heat radiating fins are arranged and is thermally connected to a first edge of each heat radiating fin. The third path which connects a downstream end of the first path and an upstream end of the second path.

### CROSS-REFERENCE TO RELATED APPLICATIONS

This is a Continuation Application of PCT Application No. PCT/JP2004/018747, filed Dec. 15, 2004, which was published under PCT Article 21(2) in Japanese.

This application is based upon and claims the benefit of priority from Japanese Patent Applications No. 2003-433931, filed Dec. 26, 2003, the entire contents of which are incorporated herein by reference.

### BACKGROUND

1. Field

One embodiment of the invention relates to a cooling apparatus of liquid-cooling type that cools a heat generating component, such as a CPU, with liquid coolant.

2. Description of the Related Art

A CPU is incorporated in electronic apparatuses such as personal computers. The CPU generates more and more heat, while operating, as its data-processing speed rises or as it performs more and more functions. The higher the temperature of the CPU, the less efficiently it operates.

To cool the CPU, so-called “cooling system of liquid cooling type” have been put to use in recent years. The cooling system uses a liquid coolant that has a far higher thermal conductivity than air.

The conventional cooling system has a heat receiving portion for receiving heat from a CPU, a heat radiating portion for radiating heat generated by the CPU, a circulation path for circulating liquid coolant between the heat receiving portion and head radiating portion, and a fan for applying cooling air to the heat radiating portion.

The heat radiating portion has a pipe and a plurality of heat radiating fins. The liquid coolant heated through the heat exchange at the heat receiving portion flows through the pipe. The heat radiating fins are shaped like a flat plate and are arranged in a row and spaced apart from one another. The pipe penetrates the center parts of the heat radiating fins. The pipe has an outer circumferential surface that is thermally connected to the center parts of the heat radiating fins, by means of, for example, soldering or the like.

The fan comprises an impeller and a fan case containing the impeller. The fan case has an outlet port, through which cooling air is discharged. The outlet port opposes the heat radiating portion. The cooling air discharged through the outlet port passes through the gaps between the heat radiating fins. The cooling air takes away the heat transferred from the liquid coolant to the pipe and heat radiating fins. The liquid coolant heated in the heat radiating portion is therefore cooled as it exchanges heat with the cooling air. Jpn. Pat. Appln. KOKAI Publication 2003-101272 discloses an electronic apparatus that incorporates a cooling apparatus that has such a heat radiating portion and such a fan.

In the cooling apparatus disclosed in this publication, the outlet port of the fan opens to the impeller in only one direction, and the opening has but a limited size. Further, the heat radiating portion must lie well within the opening of the outlet port. Inevitably, the heat radiating portion and the heat radiating fins are greatly limited in size and number, respectively. Hence, the heat radiating portion cannot have a sufficient heat radiating area and cannot radiate heat from the CPU at high efficiency.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a perspective view of an exemplary portable computer according to a first embodiment of this invention;

FIG. 2 is an exemplary perspective view of the portable computer according to the first embodiment, illustrating the positional relation that the display unit has with the intermediate unit incorporating a cooling apparatus once it has been rotated to the second position;

FIG. 3 is an exemplary another perspective view of the portable computer according to the first embodiment, illustrating the positional relation that the display unit has with the intermediate unit incorporating the cooling apparatus once it has been rotated to the second position;

FIG. 4 is an exemplary perspective view of the portable computer according to the first embodiment, illustrating the positional relation that the display unit has with the intermediate unit incorporating the cooling apparatus once it has been rotated to the first position;

FIG. 5 is an exemplary sectional view of the portable computer according to the first embodiment, illustrating the positional relation between the pump unit provided in the main unit, the radiator provided in the intermediate unit and the circulation path for circulating liquid coolant between the pump unit and the radiator;

FIG. 6 is an exemplary exploded perspective view showing the pump unit according to the first embodiment of this invention;

FIG. 7 is an exemplary perspective view of the pump housing according to the first embodiment of the present invention;

FIG. 8 is an exemplary plan view of the pump housing according to the first embodiment of the invention;

FIG. 9 is an exemplary side view of the radiator according to the first embodiment of this invention;

FIG. 10 is an exemplary sectional view taken along line F10-F10 in FIG. 5;

FIG. 11 is an exemplary sectional view of the thermal junction at which heat radiating fins are connected to the flat pipe in the first embodiment of the present invention;

FIG. 12 is a plan view of an exemplary radiator according to a second embodiment of this invention;

FIG. 13 is a plan view of an exemplary radiator according to a third embodiment of this invention;

FIG. 14 is an exemplary sectional view taken along line F14-F14 shown in FIG. 13;

FIG. 15 is a plan view of an exemplary radiator according to a fourth embodiment of the present invention;

FIG. 16 is an exemplary bottom view of the radiator according to the fourth embodiment of this invention;

FIG. 17 is an exemplary perspective view of the fin assembly of the radiator according to the fourth embodiment of this invention;

FIG. 18 is an exemplary side view of the radiator according to the fourth embodiment of this invention;

FIG. 19 is an exemplary sectional view taken along line F19-F19 in FIG. 15;

FIG. 20 is an exploded perspective view of an exemplary radiator according to a fifth embodiment of the present invention;

FIG. 21 is an exemplary perspective view of the radiator according to the fifth embodiment of the invention;

FIG. 22 is an exploded perspective view of an exemplary radiator according to a sixth embodiment of this invention;

FIG. 23 is an exemplary perspective view of the radiator according to the sixth embodiment of the invention;

FIG. 24 is an exploded perspective view of an exemplary radiator according to a seventh embodiment of the present invention;

FIG. 25 is an exemplary perspective view of the radiator according to the seventh embodiment of the invention;

FIG. 26 an exploded perspective view of an exemplary radiator according to an eighth embodiment of the present invention; and

FIG. 27 is an exemplary perspective view of the radiator according to the eighth embodiment of the invention.

### DETAILED DESCRIPTION

Various embodiments according to the invention will be described hereinafter with reference to the accompanying drawings. In general, according to one embodiment of the invention, a cooling apparatus comprises an outlet port through which cooling air is applied in a radial direction, a plurality of heat radiating fins which are arranged at intervals and which surround the outlet port, each having a first edge and a second edge located opposite to the first edge, and first to third paths in which liquid coolant flows. The first path extends in the direction the heat radiating fins are arranged and is thermally connected to the second edge of each heat radiating fin. The second path extends in the direction the heat radiating fins are arranged and is thermally connected to the first edge of each heat radiating fin. The third path which connects a downstream end of the first path and an upstream end of the second path.

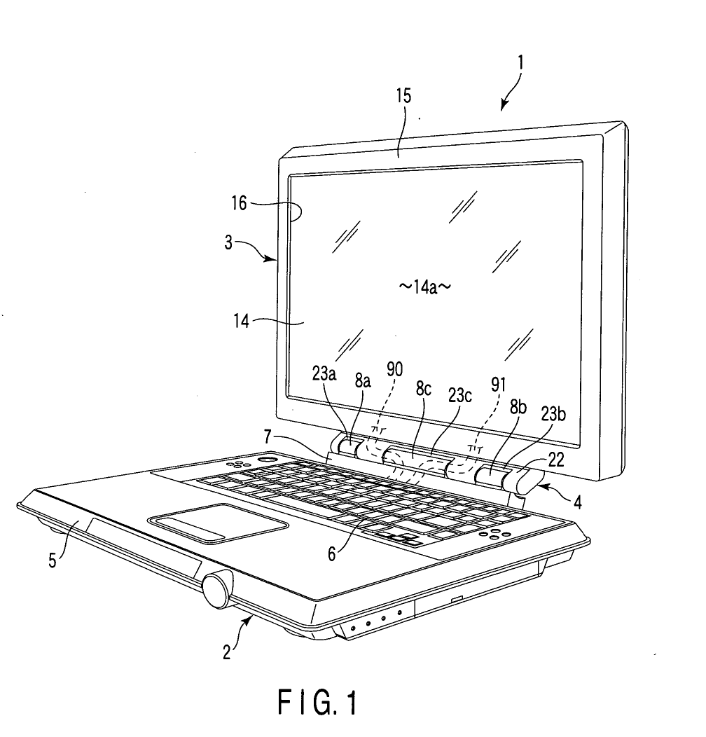

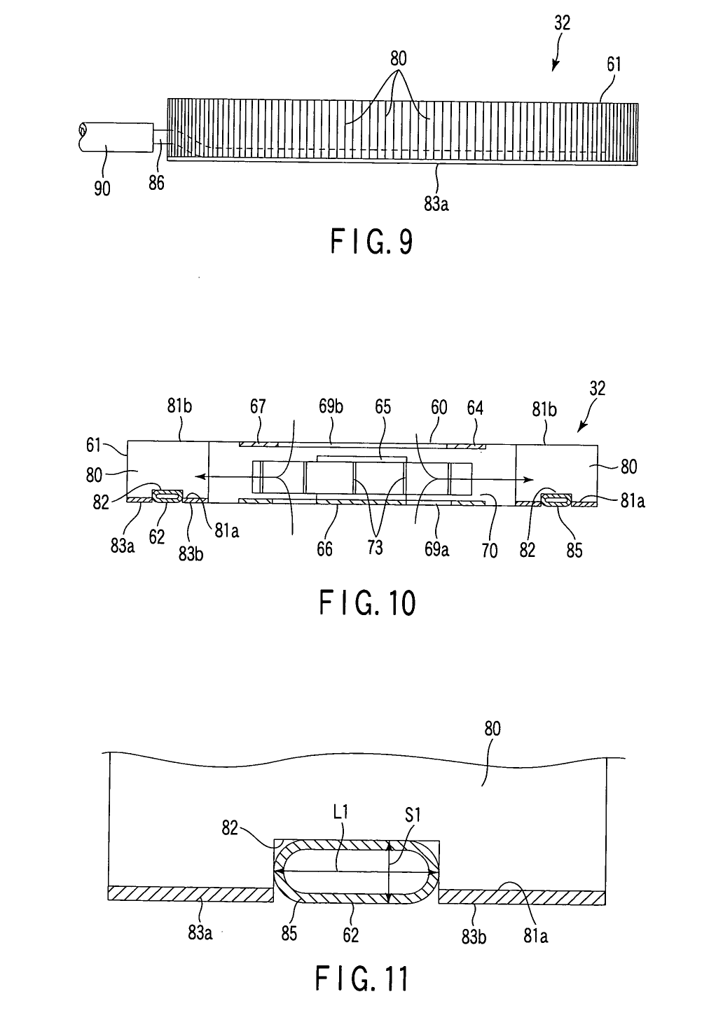

The first embodiment of the present invention will be described, with reference to FIGS. 1 to 11.

FIGS. 1 to 3 show a portable computer that is an example of an electronic apparatus. The portable computer 1 comprises a main unit 2, a display unit 3, and an intermediate unit 4. The main unit 2 has a first housing 5 that is shaped like a flat box. A keyboard 6 is provided on the upper surface of the first housing 5.

A coupling seat 7 is provided on the rear edge of the first housing 5. The coupling seat 7 extends in the widthwise direction of the first housing 5 and protrudes up from the upper surface of the first housing 5. The coupling seat 7 has first to third hollow projections 8a, 8b and 8c. The hollow projections 8a, 8b and 8c are arranged in a row, spaced apart from one another in the widthwise direction of the first housing 5.

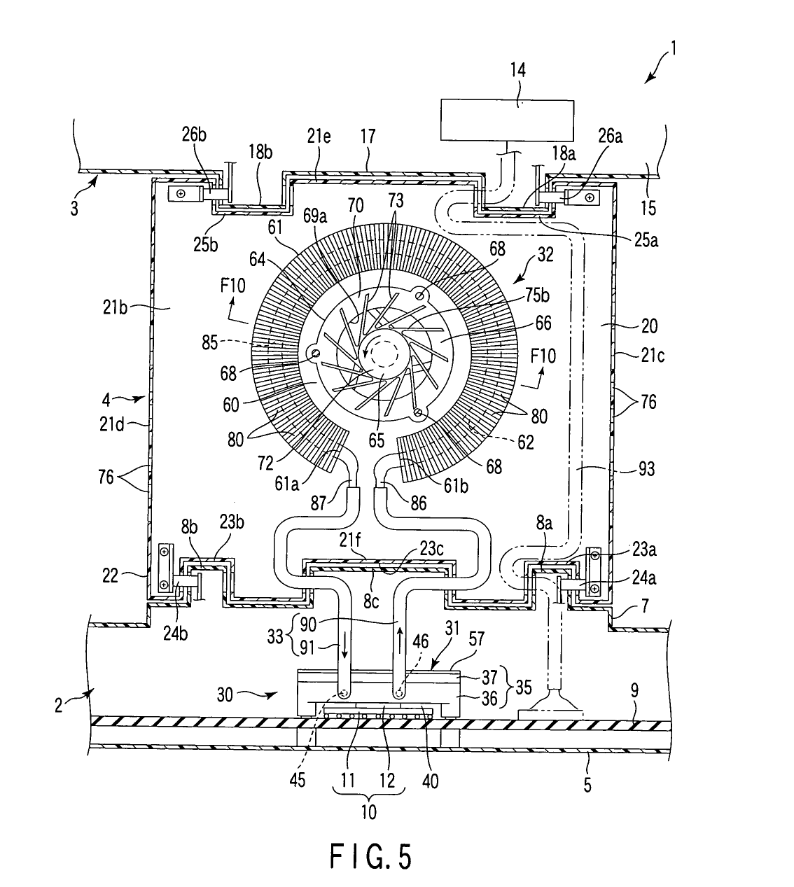

As shown in FIG. 5, the first housing 5 contains a printed circuit board 9. A CPU 10, which is a heat generating component, is mounted on the upper surface of the printed circuit board 9. The CPU 10 has a base substrate 11 and an IC chip 12 mounted on the upper surface of the base substrate 11. The IC chip 12 generates a great amount of heat while operating, because it operates at high speed and performs many functions. To keep operating in a stable state, the IC chip 12 needs to be cooled.

The display unit 3 is a component that is independent of the main unit 2. The display unit 3 comprises a liquid crystal display panel 14 and a second housing 15 containing the liquid crystal display panel 14. The liquid crystal display panel 14 has a screen 14a that displays images. The second housing 15 is shaped like a flat box, as large as the first housing 5, and has a rectangular opening 16 in the front. The screen 14a of the liquid crystal display panel 14 is exposed outside through the opening 16.

The second housing 15 has a back plate 17 located at the back of the liquid crystal display panel 14. The back plate 17 has been processed, forming a pair of hollow projections 18a and 18b as illustrated in FIG. 5. The hollow projections 18a and 18b are located at the upper part of the second housing 15. The hollow projections 18a and 18b are spaced apart in the widthwise direction of the second housing 15 and protrude toward the back of the second housing 15.

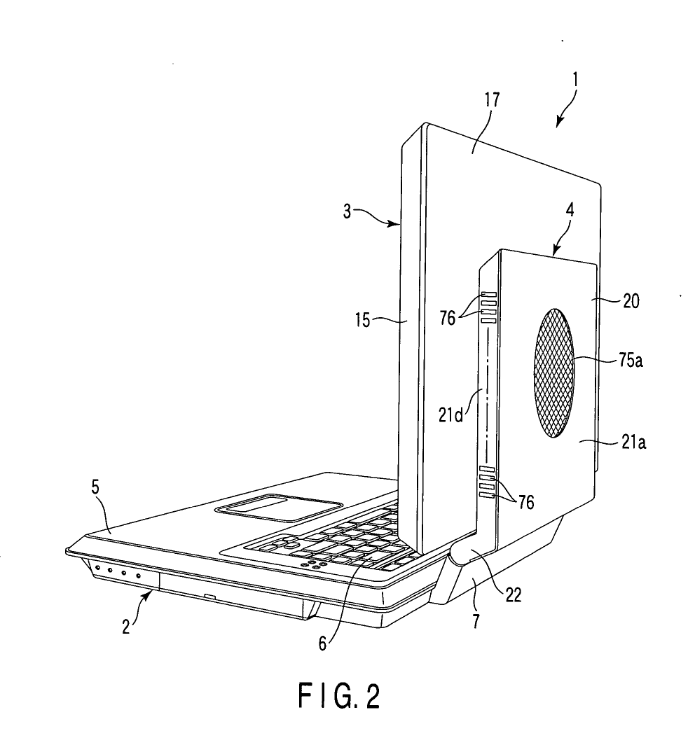

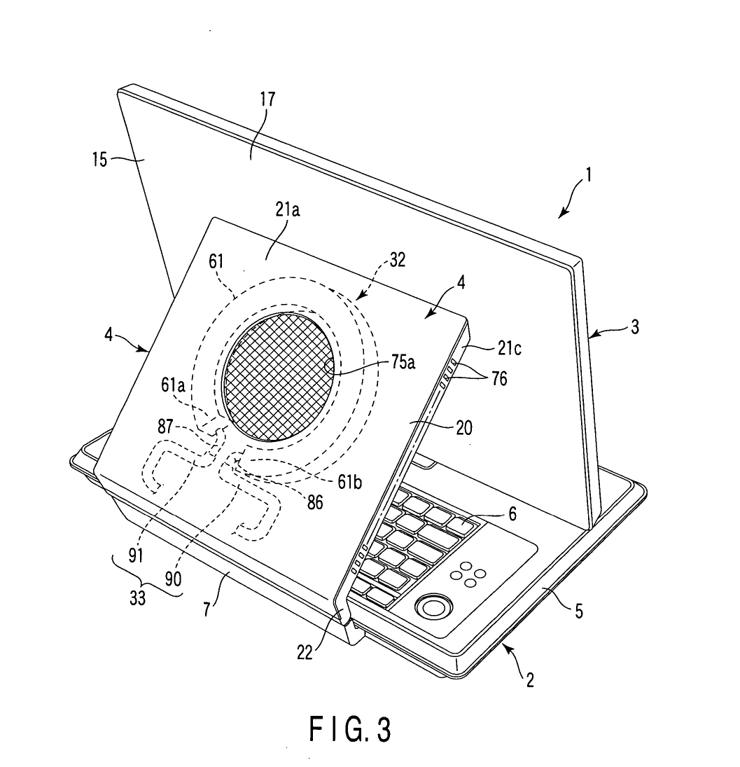

As shown in FIGS. 2 and 3, the intermediate unit 4 lies on both the main unit 2 and the display unit 3. The intermediate unit 4 has a third housing 20. The third housing 20 is shaped like a flat box and has a top plate 21a, a bottom plate 21b, left and right sidewalls 21c and 21d, and a pair of end plates 21e and 21f. The third housing 20 is less wide than the first and second housings 5 and 15.

As FIGS. 1, 2 and 5 shows, the third housing 30 has a leg part 22 at one end. The leg part 22 projects toward the coupling seat 7 and has first to third recesses 23a, 23b and 23c. The first and second recesses 23a and 23b are spaced in the widthwise direction of the third housing 20 and aligned with the first and second hollow projections 8a and 8b, respectively. The first and second hollow projections 8a and 8b are set in the first and second recesses 23a and 23b, respectively. The third recess 23c lies between the first recess 23a and the second recess 23b. The third projection 8c is set in the third recess 23c.

The leg part 22 is coupled to the coupling seat 7 by a pair of hinges 24a and 24b and can be rotated with respect to the seat 7. One hinge 24a extends between the first hollow projection 8a of the coupling seat 7 and the third housing 20. The other hinge 24b extends between the second hollow projection 8b of the coupling seat 7 and the third housing 20.

As shown in FIG. 5, the third housing 20 has a pair of recesses 25a and 25b. The recesses 25a and 25b are located at that end of the third housing 20 which faces away from the leg part 22. The recesses 25a and 25b are spaced apart in the widthwise direction of the third housing 20 and aligned with the hollow projections 18a and 18b of the second housing 15, respectively. The hollow projections 18a and 18b are set in the recesses 25a and 25b.

The third housing 20 is coupled at the other end to the back plate 17 of the second housing 15 by a pair of hinges 26a and 26b and can be rotated with respect to the back plate 17. One hinge 26a extends between one hollow projection 18a of the second housing 15 and the third housing 20. The other hinge 26b extends between the other hollow projection 18b of the second housing 15 and the third housing 20.

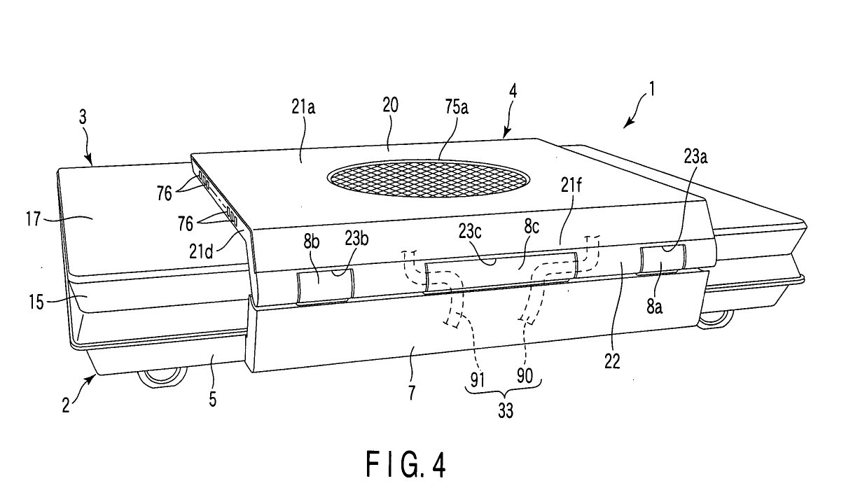

Thus, the display unit 3 is coupled to the main unit 2 by the intermediate unit 4. The display unit 3 can be rotated with respect to the main unit 2 between a first position and a second position. FIG. 4 shows the display unit 3 rotated to the first position. FIGS. 1 to 3 show the display unit 3 rotated to the second position.

At the first position, the display unit 3 lies above the main unit 2, covering the upper surface of the first housing 5 and the keyboard 6. At the second position, the display unit 3 stands up on the main unit 2, exposing the keyboard 6 and the screen 14a. While the display unit 3 remains at the second position, the intermediate unit 4 stand up at the back of the display unit 3. The display unit 3 can therefore be rotated alone, using the hinges 26a and 26b as fulcrum. Hence, the user can change the angle at which the display unit 3 stands so that he or she may see the image displayed on the screen 14a.

As FIG. 5 shows, the main unit 2 incorporates a cooling apparatus 30 of liquid cooling type. The cooling apparatus 30 is designed to cool the CPU 10 with liquid coolant such as antifreeze liquid. The cooling apparatus 30 comprises a pump unit 31, a radiator 32, and a circulation path 33. The radiator 32 is the heat radiating unit.

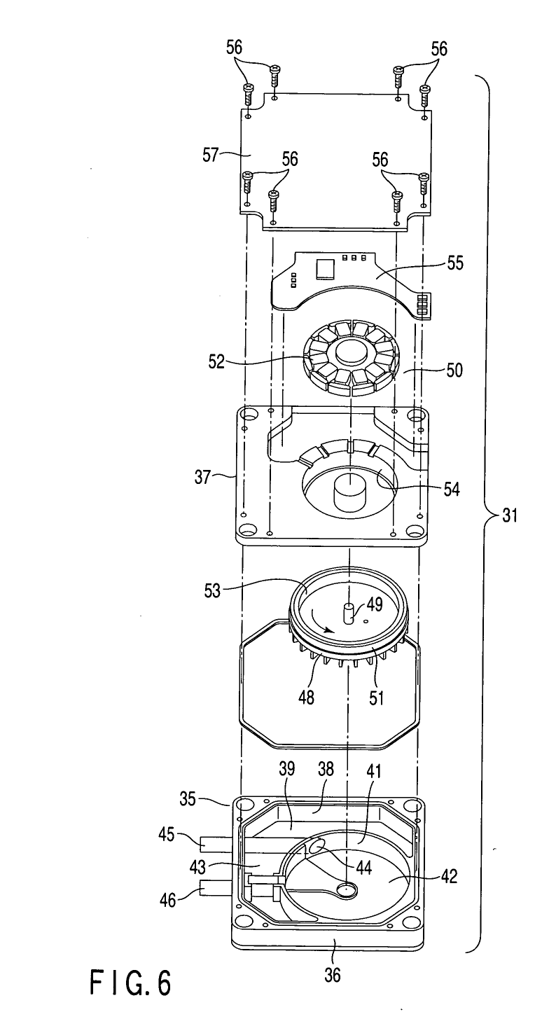

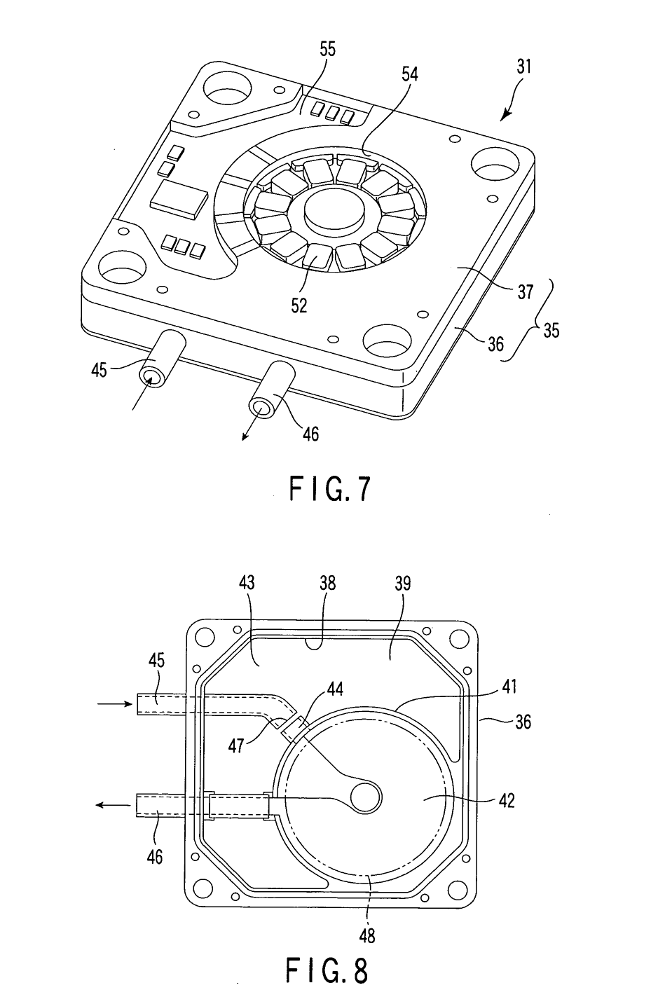

The pump unit 31 is positioned in the first housing 5. The pump unit 31 has a pump housing 35 that functions as heat receiving portion as well. As depicted in FIGS. 6 and 7, the pump housing 35 has a housing body 36 and a top cover 37. The housing body 36 is shaped like a flat box and slightly larger than the CPU 10. It is made of metal excelling in thermal conductivity, such as aluminum alloy. The housing body 36 has a recess 38 that opens upward. The recess 38 has a bottom wall 39 that faces the CPU 10. The lower surface of the bottom wall 39 is a flat heat receiving surface 40. The top cover 37 is made of synthetic resin and closes the opening of the recess 38 in liquid-tight fashion.

A ring-shaped partition wall 41 divides the interior of the pump housing 35 into a pump room 42 and a reservoir tank 43. The reservoir tank 43 is provided to store liquid coolant temporarily and surrounds the pump room 42. The partition wall 41 protrudes upward from the bottom wall 39 of the housing body 36. The partition wall 41 has a communication opening 44 that connects the pump room 42 and the reservoir tank 43.

An inlet pipe 45 and an outlet pie 46 are integrally formed with the housing body 36. The inlet pipe 45 and the outlet pipe 46 extend parallel and are spaced part. The upstream end of the inlet pipe 45 protrudes outward from one side of the housing body 36. The downstream end of the inlet pipe 45 opens to the interior of the reservoir tank 43 and is opposed to the communication opening 44 of the partition wall 41. As shown in FIG. 8, a gap 47 for separating gas and liquid from each other is provided between the downstream end of the inlet pipe 45 and the communication opening 44. The gap 47 remains below the surface of the liquid coolant stored in the reservoir tank 43 no matter in whichever position the pump housing 35 lies.

The downstream end of the outlet pipe 46 protrudes outward from that side of the housing body 36. The upstream end of the outlet pipe 46 opens to the pump room 42.

An impeller 48 is provided in the pump room 42 of the pump housing 35. The impeller 48 has a rotation shaft 49 that extends in the axial direction of the impeller 48. The rotation shaft 49 is supported by the bottom wall 39 of the recess 38 and the top cover 37 and can be rotated.

The pump housing 35 contains a motor 50 that drives the impeller 48. The motor 50 has a ring-shaped rotor 51 and a stator 52. The rotor 51 is secured to the upper surface of the impeller 48 and aligned coaxial with the impeller 48 and is provided in the pump room 42. A magnet 53 is embedded in the rotor 51. The magnet 53 has a plurality of positive poles and a plurality of negative poles. The magnet 53 rotates as the rotor 51 and impeller 48 rotate.

The stator 52 is provided in a recess 54 made in the upper surface of the top cover 37. The recess 54 extends into the rotor 51. The stator 52 therefore lies in the rotor 51 and is positioned coaxial with the rotor 51. A control board 55 for controlling the motor 50 is supported on the upper surface of the top cover 37. The control board 55 is electrically connected to the stator 52.

Electric power is supplied to the stator 52, for example, at the same time the portable computer 1 is turned on. When power is supplied to the stator 52, a rotating magnetic field is generated around the stator 52. This magnetic field combines with the magnetic field of the magnet 53 of the rotor 51. As a result, a torque develops between the stator 52 and the magnet 53, acting in the circumferential direction of the rotor 51. The torque drives the impeller 48 counterclockwise, i.e., in the direction of the arrow shown in FIG. 6.

A plurality of screws 56 fasten a back plate 57 to the upper surface of the top cover 37. The back plate 57 covers the stator 52 and the control board 55.

The pump unit 31 is positioned on the printed circuit board 9, covering the CPU 10 from above. The pump housing 35 of the pump unit 31 is secured to the bottom of the first housing 5, along with the printed circuit board 9. Since the pump housing 35 is so secured, the heat receiving surface 40 of the housing body 36 is thermally connected to the IC chip 12 of the CPU 10.

As shown in FIGS. 3 and 5, the radiator 32 of the cooling apparatus 30 is provided in the third housing 20 of the intermediate unit 4. The radiator 32 includes a fan 60, a fin assembly 61, and a passage 62. Liquid coolant flows through the passage 62.

As FIG. 10 shows, the fan 60 comprises a fan case 64 and a centrifugal impeller 65. The fan case 64 has a base 66 and a top cover 67. The base 66 and the top cover 67 are shaped like a disc and are coupled to each other with pins 68 at three points. The base 66 and the top cover 67 face each other and positioned coaxially.

The fan case 64 has a pair of inlet ports 69a and 69b and an outlet port 70. The inlet port 69a is made in the center part of the base 66, and the inlet port 69b is made in the center part of the top cover 67. The outlet port 70 is made in the outer circumference of the fan case 64 and extends in the circumferential direction of the base 66 and top cover 67.

The impeller 65 is located between the base 66 and the top cover 67. The impeller 65 has a hub 72 and a plurality of vanes 73 projecting from the hub 72 in radial direction. The hub 72 is coupled to an electric motor (not shown) secured to the base 66. The distal end of any vane 73 opposes the outlet port 70 of the fan case 64. The electric motor starts driving the impeller 65 when the power switch on the portable computer 1 is turned on or when the temperature of the CPU 10 reaches a preset value.

When the impeller 65 rotates counterclockwise, i.e., in the direction of the arrow as illustrated in FIG. 5, air outside the fan case 64 is drawn to the rotation center of the impeller 65 through the inlet ports 69a and 69b. The air, thus drawn, flows from the tips of the vanes 73 toward the outlet port 70 of the fan case 64, by virtue of a centrifugal force. The fan 60 therefore applies cooling air in radial direction from the entire circumference of the fan case 64.

The fan case 64 of the fan 60 is fixed to the inner surface of the bottom plate 31b of the third housing 20. The top plate 21a and bottom plate 21b of the third housing 20 have intake ports 75a and 75b, respectively. The intake ports 75a and 75b are opposed to the inlet ports 69a and 69b of the fan case 64, respectively.

The sidewalls 21c and 21d of the third housing 20 each have a plurality of exhaust ports 76. The exhaust ports 76 are spaced apart, arranged in a row and located at the back of the display unit 3.

As shown in FIGS. 5, 9 and 10, the fin assembly 61 has a plurality of heat radiating fins 80. The heat radiating fins 80 are shaped like a rectangular plate and are made of metal excelling in thermal conductivity, such as aluminum alloy. The heat radiating fins 80 are arranged around the outlet port 70 of the fan 60 and spaced apart from one another. In other words, the heat radiating fins 80 extend in the radial direction of the impeller 65 and in the direction in which the cooling air flows from the outlet port 70. The fin assembly 61 therefore curves in the form of an arc, surrounding the impeller 65.

The fin assembly 61 has a first end 61a and a second ends 61b. The first end 61a is located at one end as viewed in the direction in which the heat radiating fins 80 are arranged. The second end 61b is located at the other end as viewed in the direction in which the heat radiating fins 80 are arranged. The first end 61a and the second end 61b face each other, spaced apart in the circumferential direction of the fin assembly 61.

As shown in FIG. 10, each heat radiating fin 80 of the fin assembly 61 has a first edge 81a and a second edge 81b. The first and second edges 81a and 81b extend in the direction in which cooling air is applied. The first edge 81a lies at the lower end of the heat radiating fin 80. The second edge 81b lies at the upper end of the heat radiating fin 80. In other words, the first edge 81a and the second edge 81b are spaced from each other in the height direction of the heat radiating fin 80. As illustrated in FIG. 11, a recess 82 is made in the first edge 81a of the heat radiating fin 80. The recess 82 is located at the center part of the first edge 81a.

Any adjacent heat radiating fins 80 are coupled by a pair of coupling plates 83a and 83b. The coupling plates 83a and 83b are curved in the form of an arc, in the direction in which the heat radiating fins 80 are arranged. The coupling plates 83a and 83b are secured to the first edge 81a of every heat radiating fin 80 by means of soldering or the like. The heat radiating fins 80 are thereby held at regular intervals.

As FIG. 11 shows, the above-mentioned passage 62 is constituted by a flatten pipe 85 that has been prepared by flattening, for example, a copper pipe. The cross section of the flatten pipe 85 has a long axis L1 and a short axis S1. The long axis L1 and the short axis S1 extend in the lengthwise direction and height direction of the heat radiating fin 80, respectively.

As FIG. 5 shows, the flatten pipe 85 curves in the form of an arc, in the direction in which the heat radiating fins 80 are arranged, and extends over the first edge 81a of any heat radiating fin 80. The flatten pipe 85 is fitted in the recess 82 of each heat radiating fin 80 and soldered to each heat radiating fin 80. Therefore, the heat radiating fins 80 and the flatten pipe 85 constitute an integral structure, and the fins 80 and the pipe 85 are thermally connected.

The flatten pipe 85 has a coolant inlet port 86 and a coolant outlet port 87. The coolant inlet port 86 is located at the upstream end of the passage 62. The coolant outlet port 87 is located at the downstream end of the passage 62. The coolant inlet port 86 and the coolant outlet port 87 lie between the first end 61a and second end 61b of the fin assembly 61.

As shown in FIG. 5, the circulation path 33 of the cooling apparatus 30 has a first connecting tube 90 and a second connecting tube 91. The first connecting tube 90 connects the outlet pipe 46 of the pump housing 35 to the coolant inlet port 86 of the fin assembly 61. The first connecting tube 90 extends from the pump housing 35 to the third hollow projection 8c of the first housing 5, passes over the junction between one end of this hollow projection 8c and the third housing 20, and is led to the coolant inlet port 86 of the fin assembly 61.

The second connecting tube 91 connects the inlet pipe 45 of the pump housing 35 to the coolant outlet port 87 of the fin assembly 61. The second connecting tube 91 extends from the pump housing 35 to the third hollow projection 8c of the first housing 5, passes over the junction between the other end of this hollow projection 8c and the third housing 20, and is led to the coolant outlet port 87 of the fin assembly 61. Hence, liquid coolant can circulate between the pump housing 35 and the radiator 32 through the first and second connecting pipes 90 and 91.

As FIG. 5 shows, the liquid crystal display panel 14 provided in the second housing 15 is connected by a cable 93 to the printed circuit board 9 provided in the first housing 5. The cable 93 is led from the liquid crystal display panel 14 into the third housing 20 via the junction between the hollow projection 18a of the second housing 15 and the recess 25a of the third housing 20.

In the third housing 20, the cable 93 extends between the radiator 32 and the sidewall 21c and is led into the first housing 5 via the junction between the first recess 23a of the third housing 20 and the hollow projection 8a of the first housing 5.

How the cooling apparatus 30 operates will be explained.

During the use of the portable computer 1, the IC chip 12 of the CPU 10 generates heat. The heat the IC chip 12 generates propagates to the pump housing 35 through the heat receiving surface 40. The liquid coolant filled in the pump room 42 and reservoir tank 43 of the pump housing 35 absorbs most of the heat transmitted to the pump housing 35.

Electric power is supplied to the stator 52 of the motor 50 at the same time the power switch on the portable computer 1 is turned on. A torque is thereby generated between the stator 52 and the magnet 53 of the rotor 51. The rotor 52 therefore rotates, driving the impeller 48. As the impeller 48 is so driven, a pressure is applied to the liquid coolant in the pump room 42. The liquid coolant is forced out through the outlet pipe 46 and guided into the radiator 32 through the first connecting pipe 90.

More specifically, the liquid coolant heated through heat exchange in the pump housing 35 is pumped into the flatten pipe 85 via the coolant inlet port 86 of the fin assembly 61. The liquid coolant flows through the flatten pipe 85 toward the coolant outlet port 87. As the coolant so flows, the heat generated by the IC chip 12 and absorbed into the liquid coolant propagates to the flatten pipe 85 and thence to the heat radiating fins 80.

Assume that the impeller 65 of the fan 60 is driven during the use of the portable computer 1. Then, cooling air is applied in radial direction through the outlet port 70 that is made in the entire outer circumference of the fan case 64. The cooling air thus applied flows through the gaps between the heat radiating fins 80 of the fin assembly 61. The heat radiating fins 80 and the flatten pipe 85 are thereby cooled. Thus, most of the heat transmitted to the heat radiating fins 80 and the flatten pipe 85 is released from the third housing 20 as the cooling air flows outward through the exhaust ports 76.

The liquid coolant cooled while flowing through the flatten pipe 85 is guided into the inlet pipe 45 of the pump housing 35 through the second connecting pipe 91. The liquid coolant is supplied from the downstream end of the inlet pipe 45 into the reservoir tank 43. The liquid coolant flowing through the flatten pipe 85 may contain bubbles. In this case, the bubbles are removed from the liquid coolant in the reservoir tank 43.

The liquid coolant supplied back into the reservoir tank 43 absorbs the heat generated by the IC chip 12 until it is drawn into the pump room 42 through the communication opening 44. The liquid coolant is drawn from the reservoir tank 43 into the pump room 42 via the communication opening 44 as the impeller 48 is rotated. A pressure is again applied to the liquid coolant drawn into the pump room 42, which supplied from the outlet pipe 46 toward the radiator 32.

This cycle of operations is repeated, whereby the heat of the IC chip 12 is transferred to the fin assembly 61. The cooling air that flows through the fin assembly 61 takes the heat away from the third housing 32.

In the radiator 32 according to the first embodiment, described above, the fan 60 has the outlet port 70 made in the entire outer circumference of the fan case 64 and applies cooling air in radial direction from the entire circumference of the impeller 65. The fin assembly 61 that receives the cooling air has a plurality of heat radiating fins 80 that are arranged, spaced apart from one another and surrounding the outlet port 70. The flatten pipe 85 into which the heated liquid coolant is guided curves in the form of an arc and thermally connected to the first edge 81a of any heat radiating fin 80.

With this configuration, a number of heat radiating fins 80 are arranged, surrounding the fan 60. This increases the area at which the heat radiating fins 80 contact the cooling air. Therefore, the heat radiating fins 80 can efficiently release the heat from the liquid coolant flowing in the flatten pipe 85. Hence, the heat radiating efficiency of the radiator 32 is enhanced.

In addition, the fin assembly 61 will not greatly protrude from the fan 60 since it is arranged coaxially with the fan 60. The radiator 32 can therefore be compact as a whole. The radiator 32 can be incorporated in the third housing 20 limited in size, without the necessity of taking any special measures.

Further, the area at which the each heat radiating fin 80 contacts the flatten pipe 85 increases, because each heat radiating fin 80 has the recess 82 in the first edge 81a and the flatten pipe 85 is fitted in the recess 82. This increases. Hence, heat can be efficiently transferred from the flatten pipe 85 to the heat radiating fins 80. As a result, the surface temperature of each heat radiating fin 80 readily rises, efficiently radiating the heat of the IC chip 12 into the liquid coolant, from the surface of each heat radiating fin 80.

In the first embodiment described above, the radiator is provided in the intermediate unit that couples the main unit and the display unit. Nonetheless, this invention is not limited to the first embodiment. For example, the radiator may be incorporated either in the first housing of the main unit or in the second housing of the display unit.

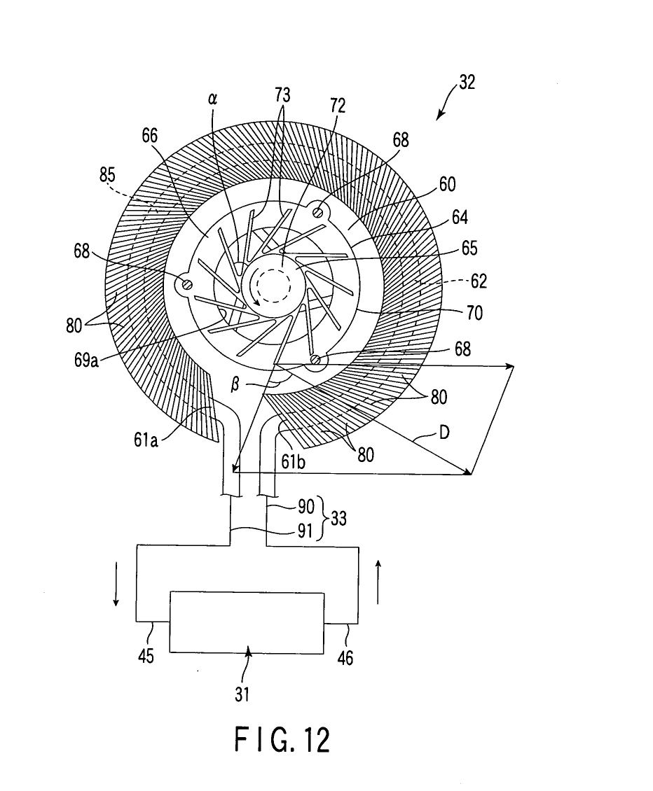

FIG. 12 show a second embodiment of the present invention.

The second embodiment differs from the first embodiment, mainly in the extending direction of the heat radiating fins 80 of the fin assembly 61. In another respects, the second embodiment is identical to the first embodiment.

As shown in FIG. 12, the vanes 73 of the fan 60 extend in the tangential direction of the hub 72, inclining backwards with respect to the direction in which the impeller 65 rotates. The inclination angle α of the vanes 73 has been determined by the rate at which the cooling air should be applied and some other factors.

When the impeller 65 is driven in the direction of the arrow, air is drawn to the center of rotation of the impeller 65. This air is cooling air, which is applied from the distal ends of the vanes 73 to the outlet port 70. The direction D in which the cooling air is applied is almost at right angles to each vane 73. The angle β between the direction D in which the cooling air is applied and the direction in which each vane 73 extends is usually 80° to 105°, depending on the inclination angle α of the vane 73.

Hence, in the second embodiment, each of the heat radiating fins 80 that are so arranged to surround the impeller 65 extends in the direction in which the cooling air is applied from the vanes 73.

In this configuration, the direction in which the cooling air is applied from the outlet port 70 of the fan case 64 toward the fin assembly 61 is identical to the direction in which each heat radiating fin 80 extends. The cooling air can therefore easily flow into the gap between any two adjacent heat radiating fins 80. As a result, the cooling air can efficiently cool the fin assembly 61. This increases the heat radiating efficiency of the radiator 32.

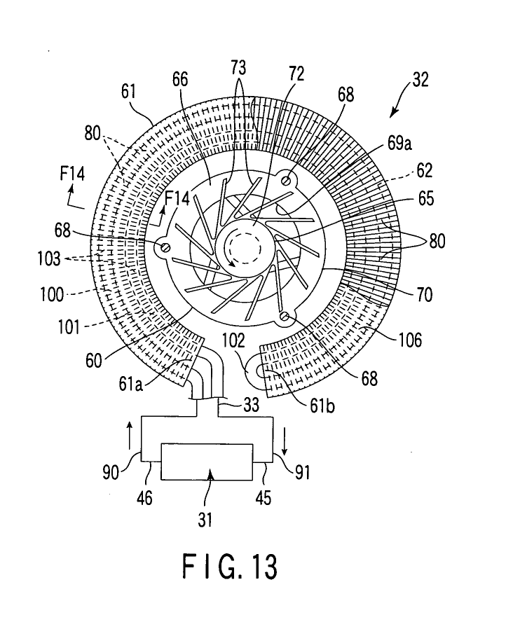

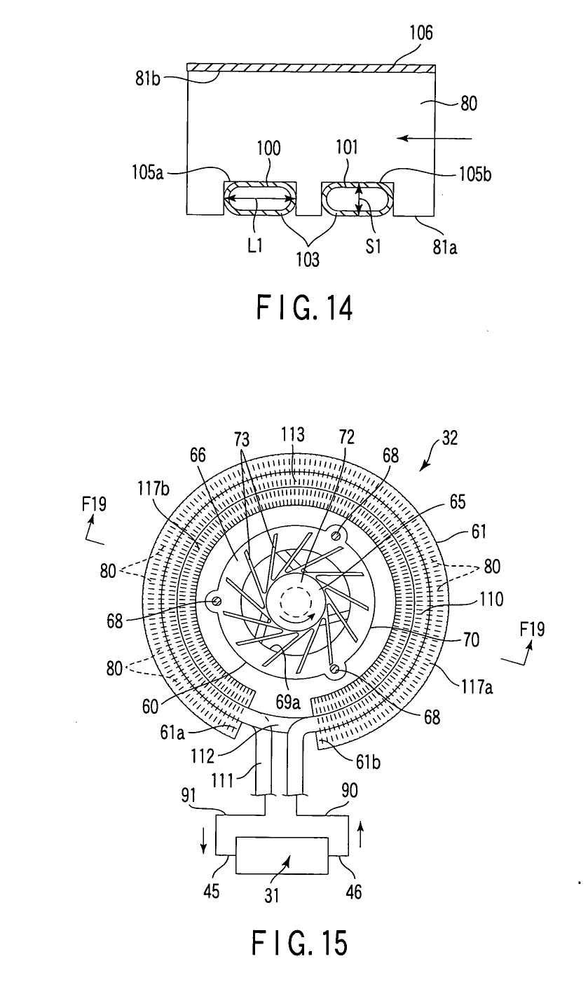

FIGS. 13 and 14 show a third embodiment of the present invention.

The third embodiment differs from the first embodiment, mainly in the shape of the passage 62 provided in the radiator 32.

As shown in FIG. 13, the passage 62 has first to third coolant paths 100, 101 and 102. The first coolant path 100 extends from the first end 61a of the fin assembly 61 to the second end 61b thereof. The second coolant path 101 extends from the second end 61b of the fin assembly 61 to the first end 61a thereof. The third coolant path 102 connects the downstream end of the first coolant path 100 and the upstream end of the second coolant path 101.

The first and second coolant paths 100 and 101 curve in the form of an arc and extend in the direction in which the heat radiating fins 80 are arranged. The paths 100 and 101 are concentric with the impeller 65. Further, the second coolant path 101 is located between the first coolant path 100 and the fan 60.

The upstream end of the first coolant path 100 and the downstream end of the second coolant path 101 protrude from the first end 61a of the fin assembly 61. The third coolant path 102 is located between the first end 61a and second end 61b of the fin assembly 61. The first connecting pipe 90 connects the upstream end of the first coolant path 100 to the outlet pipe 46 of the pump unit 31. The second connecting pipe 91 connects the downstream end of the second coolant path 101 to the inlet pipe 45 of the pump unit 31.

The first to third coolant paths 100, 101 and 102 have been formed by bending one flatten pipe 103. As FIG. 14 depicts, the cross section of the flatten pipe 103 has a long axis L1 and a short axis S1. The long axis L1 and the short axis S1 extend in the lengthwise direction and height direction of the heat radiating fin 80, respectively.

First and second recesses 105a and 105b are made in the first edge 81a of each heat radiating fin 80. The first and second recesses 105a and 105b are spaced apart in the lengthwise direction of the heat radiating fin 80. The first coolant path 100 is fitted in the first recess 105a of each fin 80 and is soldered to the fin 80. The second coolant path 101 is fitted in the second recess 105b of each fin 80 and is soldered to the fin 80. Thus, the first coolant path 100 and the second coolant path 101 are thermally connected to the heat radiating fins 80.

A connecting plate 106 curving in the form of an arc is soldered to the second edge 81b of every heat radiating fin 80. The heat radiating fins 80 are therefore coupled by the first coolant path 100, second coolant path 101 and connecting plate 106. Thus coupled, any two adjacent fins 80 are kept spaced by a specific distance.

In this configuration, the liquid coolant heated in the pump unit 31 is first supplied into the first coolant path 100 of the fin assembly 61. The liquid coolant then flows from the first coolant path 101 into the second coolant path 101 through the third coolant path 102, reaching the downstream end of the second coolant path 101. While flowing so, the liquid coolant transfers the heat of the IC chip 12 to the heat radiating fins 80.

In the configuration described above, the liquid coolant guided from the pump housing 35 to the fin assembly 61 first flows from the first end 61a of the fin assembly 61 to the second end 61b thereof and then from the second end 61b back to the first end 61a. Hence, the liquid coolant passage extending through the fin assembly 61 is twice as long as in the first embodiment. In other words, heat is transferred to each heat radiating fin 80 from both the first coolant path 100 and the second coolant path 101.

In addition, the area at which the each heat radiating fin 80 contacts the first and second coolant paths 100 and 101 increases because the first and second coolant paths 100 and 101 are fitted in the first and second recesses 105a and 105b made in each fin 80. Heat can therefore be efficiently transferred to the heat radiating fins 80 from the liquid coolant flowing through the first and second coolant paths 100 and 101.

As a result, the surface temperature of each heat radiating fin 80 rises and the heat readily propagates to the corners of each heat radiating fin 80. The heat of the liquid coolant can be efficiently radiated from the surface of each heat radiating fin 80. This enhances the heat radiating efficiency of the radiator 32.

In the above-described configuration, the cooling air applied through the outlet port 70 of the fan 60 flows as indicated by the arrow in FIG. 14. First, it flows over the thermal junction between the second coolant path 101 and the heat radiating fins 80. Then, it flows over the thermal junction between the first coolant path 100 and the heat radiating fins 80. In other words, the first cooling path 100 is located downstream of the second coolant path 101 with respect to the direction in which the cooling air flows.

The thermal junction between the second coolant path 101 and the heat radiating fins 80 is low, because the liquid coolant flowing in the second coolant path 101 has already been cooled in the first coolant path 100 by virtue of the heat exchange with the heat radiating fins 80. On the other hand, the thermal junction between the first coolant path 100 and the heat radiating fins 80 is high, because the liquid coolant heated to a high temperature is guided first to the first coolant path 100. The temperature of the cooling air therefore greatly rises as the cooling air passes by the thermal junction between the first coolant path 100 and the heat radiating fins 80.

In the third embodiment, the thermal junction between the first coolant path 100 and the heat radiating fins 80 lies downstream of the second coolant path 101 with respect to the direction in which the cooling air flows. Hence, the cooling air heated as while passing by the thermal junction between the first coolant path 100 and the heat radiating fins 80 would not be guided to the thermal junction between the second coolant path 101 and the heat radiating fins 80.

As a result, the cooling air heated does not influence the second coolant path 101. This can prevent a temperature rise of the liquid coolant flowing from the radiator 32 back to the pump unit 31.

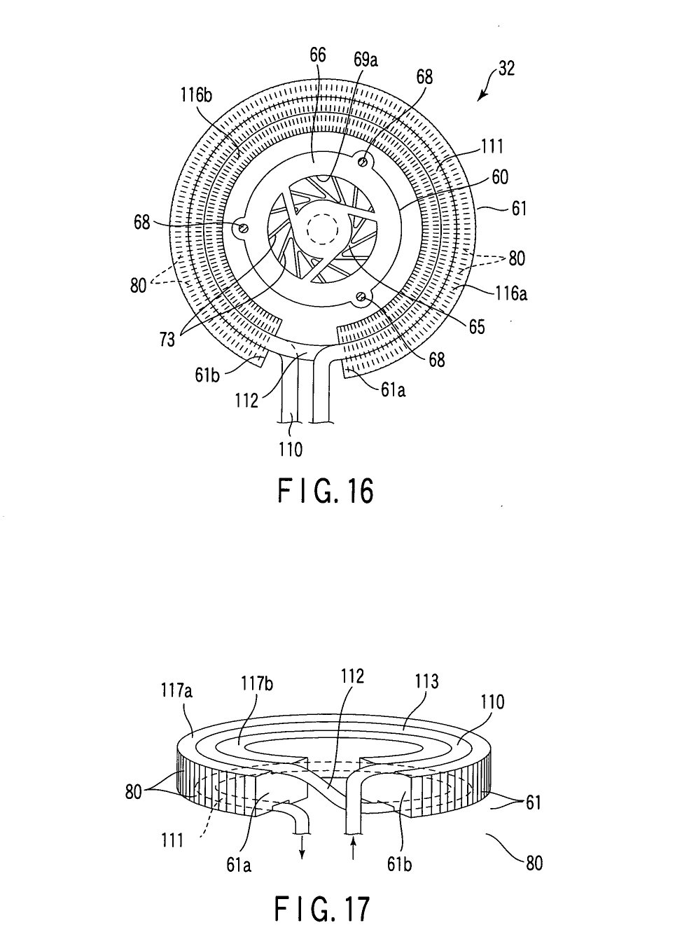

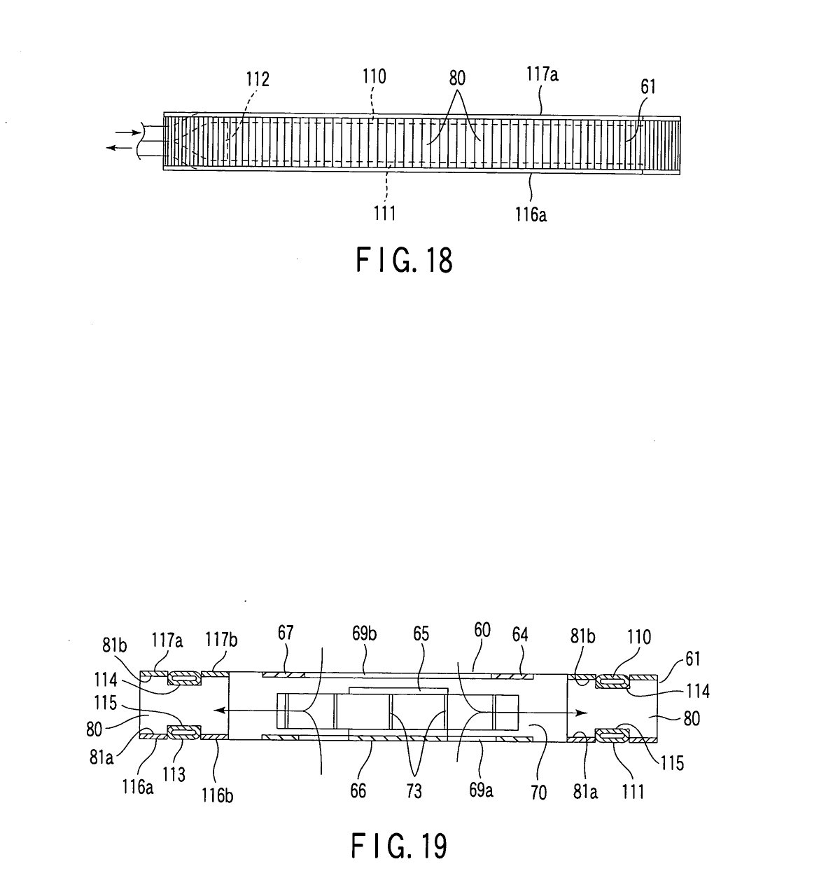

FIGS. 15 to 19 illustrate a fourth embodiment of this invention.

The fourth embodiment differs from the first embodiment that the coolant path coupled to the fin assembly 61 of the radiator 32 extends in a different way.

As shown in FIGS. 15 to 17, the fin assembly 61 has first to third paths 110 to 112 in which liquid coolant flows. The first to third coolant paths 110 to 112 have been formed by bending one flatten pipe 113.

The first path 110 curves in the form of an arc, in the direction in which heat radiating fins 80 are arranged. It contacts the second edge 81b of each heat radiating fin 80, extending over any two adjacent fins 80. The upstream end of the first path 110 lies at the second end 61b of the fin assembly 61. The downstream end of the first path 110 lies at the first end 61a of the fin assembly 61. The upstream end of the first path 110 is connected to the outlet pipe 46 of the pump unit 31 by the first connecting pipe 90. As shown in FIG. 19, the first path 110 is fitted in a recess 114 made in the second edge 81b of each heat radiating fin 80 and is soldered to each heat radiating fin 80.

The second path 111 curves in the form of an arc, in the direction in which heat radiating fins 80 are arranged. It contacts the first edge 81a of each heat radiating fin 80, extending over any two adjacent fins 80. The upstream end of the second path 111 lies at the second end 61b of the fin assembly 61. The downstream end of the second path 111 lies at the first end 61a of the fin assembly 61. The downstream end of the second path 111 is connected to the inlet pipe 45 of the pump unit 31 by the second connecting pipe 91. As shown in FIG. 19, the second path 111 is fitted in a recess 115 made in the first edge 81a of each heat radiating fin 80 and is soldered to each heat radiating fin 80.

The first path 110 and the second path 111 are spaced in the direction of height of the heat radiating fins 80. The first and second paths 110 and 111 are concentrically arranged, surrounding the impeller 65 of the fan 60.

The third path 112 is located between the first end 61a and second end 61b of the fin assembly 61. The third path 112 extends slantwise to the direction of height of the heat radiating fins 80, coupling the downstream end of the first path 110 and the upstream end of the second path 111.

A pair of connecting plates 116a and 116b are soldered to the first edge 81a of every heat radiating fin 80. The connecting plates 116a and 116b curve in the form of an arc, in the direction in which the heat radiating fins 80 are arranged. Similarly, two connecting plates 117a and 117b are soldered to the second edge 81b of every heat radiating fins 80. The connecting plates 117a and 117b curve in the form of an arc, in the direction in which the heat radiating fins 80 are arranged.

A plurality of heat radiating fins 80 are thus coupled to one another by the first path 110, second path 111 and connecting plates 116a, 116b, 117a and 117b. Any adjacent heat radiating fins 80 are therefore spaced apart by a specific distance.

In this configuration, the liquid coolant heated in the pump unit 31 is first guided to the first path 110 and then flows over the second edges 81b of the heat radiating fins 80, one after another. After reaching the downstream end of the first path 110, the liquid coolant is guided to the second path 111 and then flows over the first edges 80a of the heat radiating fins 80, one after another. As the liquid coolant flows so, heat is transferred from the liquid coolant to the heat radiating fins 80.

In the fourth embodiment, the liquid coolant guided from the pump unit 31 to the radiator 32 flows back to the pump unit 31 after it goes through the first and second paths 110 and 111, twice around the fin assembly 61. The fin assembly 61 therefore has a flow path for the liquid coolant, which is twice as long as in the fist embodiment described above. Heat propagates from the liquid coolant to each heat radiating fin 80 via two paths, i.e., the first path 110 and the second path 111.

Further, the first path 110 is fitted in the recess 114 made in the second edge 81b of every heat radiating fin 80, and the second path 111 is fitted in the recess 115 made in the first edge 81a of every heat radiating fin 80. Namely, the area at which each heat radiating fin 80 contacts the first and second paths 110 and 111 is larger than in the first embodiment. Heat can therefore be efficiently transferred from the liquid coolant to the heat radiating fins 80 while the coolant is flowing through the first and second paths 110 and 111.

Hence, the more the surface temperature of each heat radiating fin 80 rises, the more easily the heat propagates to the corners of the heat radiating fin 80. Heat can be efficiently radiated from the surface of each heat radiating fin 80. This increases the heat radiating performance of the radiator 32.

While the fin assembly 61 remains in a horizontal position as shown in FIG. 17, the third path 112 inclines downwards from the downstream end of the first path 110 to the upstream end of the second path 111. The liquid coolant therefore flows downward in the third path 112. As a result, the liquid coolant flowing in the first to third paths 110, 111 and 112 need not be forced upward against the gravitation. It is therefore possible to decrease the resistance the liquid coolant receives as it passes through the first to third paths 110, 111 and 112.

In other word, the load on the pump unit 31 that forces the liquid coolant out is reduced. The liquid coolant can therefore be circulated between the pump unit 31 and the radiator 32, without exerting a great force on the liquid coolant.

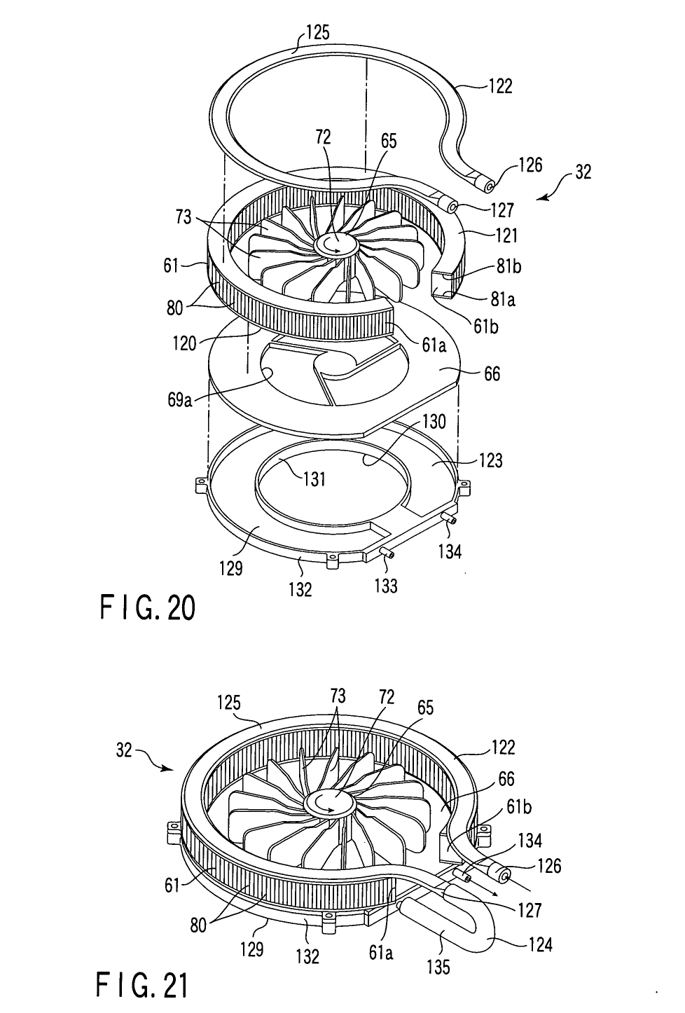

FIGS. 20 and 21 show a radiator 32 according to a fifth embodiment of the present invention.

As shown in FIG. 20, the fin assembly 61 of the radiator 32 has first and second connecting plates 120 and 121. The first and second connecting plates 120 and 121 curve in the form of an arc, in the direction in which the heat radiating fins 80 are arranged. The first connecting plate 120 is soldered to the first edge 81a of every heat radiating fin 80. The first connecting plate 120 couples the heat radiating fins 80 and is thermally connected to the heat radiating fins 80. The second connecting plate 121 is soldered to the second edge 81b of every heat radiating fin 80. The second connecting plate 121 couples the heat radiating fins 80 and is thermally connected to the heat radiating fins 80.

The fin assembly 61 has first to third paths 122, 123 and 124 in which liquid coolant flows. The first path 122 is constituted by a flatten pipe 125. The flatten pipe 125 curves in the form of an arc, in the direction in which the heat radiating fins 80 are arranged, and is soldered to and laid on the second connecting plate 121.

The upstream and downstream ends of the flatten pipe 125 protrude from the first and second ends 61a and 61b of the fin assembly 61, respectively. The upstream end of the flatten pipe 125 makes a coolant inlet port 126, at which heated liquid coolant flows in. The downstream end of the flatten pipe 125 makes a coolant outlet port 127, at which the liquid coolant flows out.

An outer cover 129 is provided beneath the base 66 that supports the impeller 65. The base 66 and the outer cover 129 are discs that have almost the same outside diameter as the fin assembly 61. The outer circumference of the base 66 is aligned with that of the fin assembly 61. The first connecting plate 120 of the fin assembly 61 is laid on the upper surface of the base 66, with its outer circumference aligned with that of the base 66.

The outer cover 129 has a through hole 130 in its center part. The through hole 130 communicates with the inlet port 69a of the base 66. An inner wall 131 is provided, extending upwards from the rim of the through hole 130. The distal end of the inner wall 131 abuts on the lower surface of the base 66. An outer wall 132 is provided, extending upwards from the outer circumferential edge of the outer cover 129. The distal end of the outer wall 132 abuts on the lower surface of the base 66.

Thus, the outer cover 129 defines the second path 123, jointly with the base 66. The second path 123 has a flat cross section and curves in the form of an arc, along the fin assembly 61.

As illustrated in FIG. 20, the outer cover 129 has a coolant inlet port 133 and a coolant outlet port 134. The coolant inlet port 133 and the coolant inlet port 134 are located near the first end 61a and second end 61b of the fin assembly 61, respectively. The coolant inlet port 133 is connected to the upstream end of the second path 123. The coolant outlet port 134 is connected to the downstream end of the second path 123.

The third path 124 is a soft pipe 135 such as a rubber tube. The pipe 135 connects the coolant inlet port 133 of the second path 123 to the coolant outlet port 127 of the first path 122.

In this configuration, the liquid coolant heated is first guided to the coolant inlet port 126 of the first path 122 and then flows in the first path 122 in the circumferential direction of the fin assembly 61. After reaching the downstream end of the first path 122, the liquid coolant is guided through the third path 124 to the coolant inlet port 133 of the second path 123. Then, the liquid coolant flows in the second path 123, in the circumferential direction of the fin assembly 61. While the liquid coolant is so flowing, heat is transferred from the coolant to the heat radiating fins 80 of the fin assembly 61. The liquid coolant that has reached the downstream end of the second path 123 flows from the coolant outlet port 134.

In the fifth embodiment, the liquid coolant guided to the radiator 32 flows twice around the fin assembly 61, through the first and second paths 122 and 123 curing in the form of an arc. The fin assembly 61 therefore has a flow path for the liquid coolant, which is twice as long as in the fist embodiment described above. Thus, heat propagates from the liquid coolant to each heat radiating fin 80 via two paths, i.e., the first path 122 and the second path 123.

Hence, the more the surface temperature of each heat radiating fin 80 rises, the more easily the heat propagates to the corners of the heat radiating fin 80. Heat can be efficiently radiated from the surface of each heat radiating fin 80. This increases the heat radiating performance of the radiator 32.

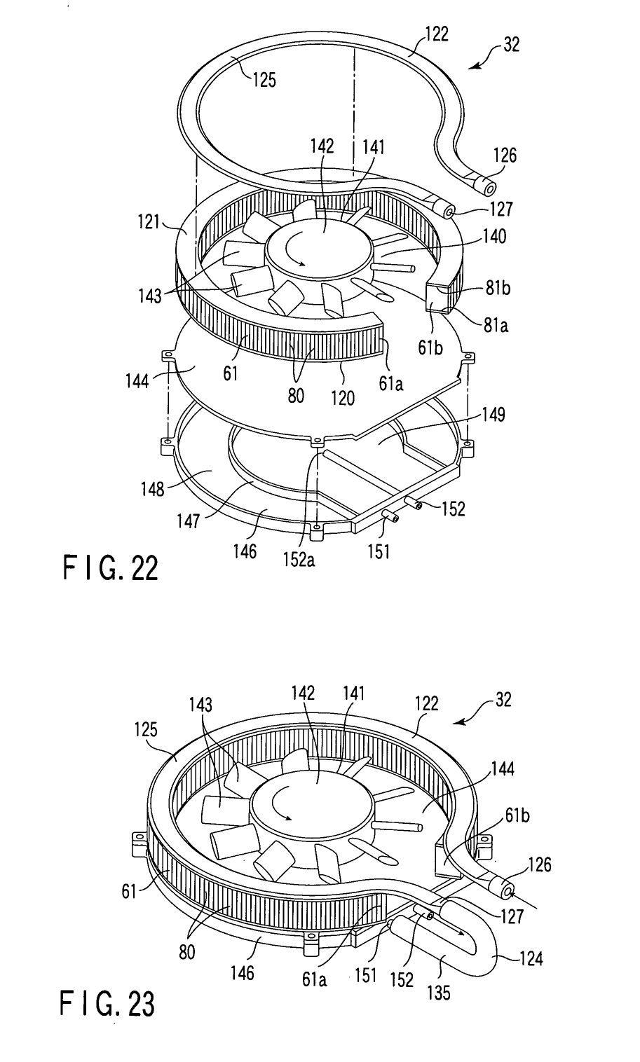

FIGS. 22 and 23 depict a radiator 32 according to a sixth embodiment of the present invention.

The sixth embodiment differs from the fifth embodiment, mainly in the use of an axial-flow fan 140 and the structure of the second path for liquid coolant. In any other respects, this radiator 32 is identical to the fifth embodiment.

The fan 140 has an impeller 141. The impeller 141 comprises a hub 142 and a plurality of vanes 143. The hub 142 has its center aligned with the axis of the impeller 141. The vanes 142 project from the hub 142 in the radial direction thereof. The hub 142 is connected to the shaft of a motor (not shown), which in turn supported on the center part of a base 144. The base 144 is shaped like a disc, having almost the same outside diameter as the fin assembly 61. The base 144 has its outer circumference aligned with the circumference of the fin assembly 61. The first connecting plate 120 of the fin assembly 61 is laid on the upper surface of the base 144, with its outer edge aligned with the circumference of the base 144.

The vanes 143 of the impeller 141 incline to the axis of the impeller 141. When the impeller 141 is driven, air flows in the axial direction of the impeller 141. The air is applied to the base 144 and flows in a different direction, i.e., the radial direction of the impeller 141. The air, or cooling air, flows to the heat radiating fins 80 of the fin assembly 61.

An outer cover 146 is provided at the lower surface of the base 144. The outer cover 146 defines a closed space, jointly with the base 144. This space is divided by a partition wall 147 into a heat transfer chamber 148 and a reservoir tank 149. The reservoir tank 149 serves as a second path, as well. The heat transfer chamber 148 faces the fin assembly 61 across the base 144 and extends in the circumferential direction of the fin assembly 61. The heat transfer chamber 148 surrounds the reservoir tank 149.

The outer cover 146 has an inlet pipe 151 and an outlet pipe 152. Liquid coolant flows in through the inlet pipe 151 and flows out through the outlet pipe 152. The inlet pipe 151 and the outlet pipe 152 are located near the first and second ends 61a and 61b of the fin assembly 61, respectively, and open to the reservoir tank 149. The inlet pipe 151 is connected to the third path 124, which in turn is connected to the coolant outlet port 127 of the first path 122.

As FIG. 22 shows, the outlet pipe 152 extends farther into the reservoir tank 149 than the inlet pipe 15 does. The outlet pipe 152 has a coolant inlet port 152a that lies in the middle part of the reservoir tank 149. The coolant inlet port 152a remains immersed in the liquid coolant stored in the reservoir tank 149, whichever position the radiator 32 takes.

In this configuration, the liquid coolant heated is first guided to the coolant inlet port 126 of the first path 122 and then flows in the first path 122, in the circumferential direction of the fin assembly 61. The liquid coolant that has reached the downstream end of the first path 122 is guided into the reservoir tank 149 through the third path 124 and the inlet pipe 151. The liquid coolant is temporarily stored in the reservoir tank 149.

The liquid coolant is forced into the reservoir tank 149 through the inlet pipe 151. The liquid flowing in the first path 122 may contain bubbles. In this case, the bubbles are removed from the liquid coolant in the reservoir tank 149. The coolant inlet port 152a of the outlet pipe 152 remains immersed in the liquid coolant stored in the reservoir tank 149. Therefore, only the liquid coolant is drawn into the outlet pipe 152.

In the sixth embodiment, the inlet pipe 151 and the outlet pipe 152 constitute a gas-liquid separating mechanism that removes bubbles from the liquid coolant. The gas-liquid separating mechanism is integral with the reservoir tank 149.

The heat transfer chamber 148, which curves along the fin assembly 61, surrounds the reservoir tank 149. The heat of the liquid coolant temporarily stored in the reservoir tank 149 is therefore transmitted from the heat transfer chamber 148 via the base 144 to the heat radiating fins 80 of the fin assembly 61.

In the sixth embodiment described above, the liquid coolant guided to the radiator 32 flows through the first path 122 along the fin assembly 61 and flows into the reservoir tank 149 surrounded by the fin assembly 61. The fin assembly 61 therefore has a flow path for the liquid coolant, which is twice as long as in the fist embodiment. As a result, heat propagates from the liquid coolant to each heat radiating fin 80 from two components, i.e., the first path 122 and the reservoir tank 149.

Therefore, the more the surface temperature of each heat radiating fin 80 rises, the more easily the heat propagates to the corners of the heat radiating fin 80. Heat can be efficiently radiated from the surface of each heat radiating fin 80. This increases the heat radiating performance of the radiator 32.

Further, heat can be transferred from the liquid coolant directly to the base 144 in the above-described configuration, because the base 144 supporting the impeller 141 and the outer cover 146 constitute the reservoir tank 149 that temporarily stores the liquid coolant. When the impeller 141 of the fan 140 is driven, the air flows in the axial direction of the impeller 141. This air, or cooling air, is applied to the base 144. The base 144 is thereby cooled at high efficiency. Namely, the cooling air takes heat of the liquid coolant from the base 144.

Thus, the liquid coolant temporarily stored in the reservoir tank 149 can be effectively cooled. This helps to enhance the heat radiating efficiency of the radiator 32.

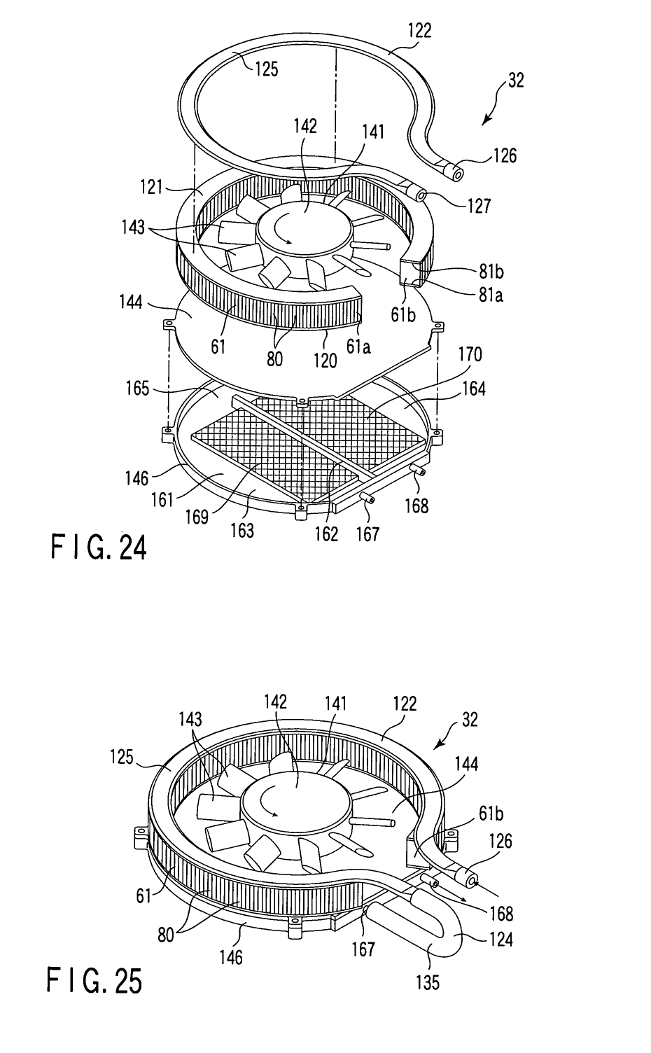

FIGS. 24 and 25 show a radiator 32 according to a seventh embodiment of the present invention.

The seventh embodiment differs from the sixth embodiment in the structure of the second path. In any other respects, this radiator 32 is identical to the sixth embodiment.

As shown in FIG. 24, the outer cover 146 defines a second path 161, jointly with the base 144. The second path 161 has a flat cross section. The second path 161 is divided by a partition wall 162 into a first coolant path 163 and a second coolant path 164. The first and second coolant paths 163 and 164 are connected by a communication path 165 that lies near the outer circumference of the outer cover 146.

The outer cover 146 has a coolant inlet port 167 and a coolant outlet port 168. The coolant inlet port 167 and the coolant outlet port 168 are provided far from the communication 165, across the first and second coolant paths 163 and 164. The ports 167 and 168 are located near the first and second ends 61a and 61b of the fin assembly 61, respectively.

The coolant inlet port 167 is provided at the upstream end of the first coolant path 163. The coolant outlet port 168 is provided at the downstream end of the second coolant path 164. The coolant inlet port 167 is connected by the third path 124 to the coolant outlet port 127 of the first path 122.

The first and second coolant paths 163 and 164 contain heat diffusing members 169 and 170, respectively. The heat diffusing members 169 and 170 are, for example, square metal nets. The metal nets are interposed between the base 144 and the outer cover 146. Therefore, the heat diffusing members 169 and 170 are thermally connected to the base 144 and the outer cover 146.

In this configuration, the liquid coolant heated is guided to the coolant inlet port 126 of the first path 122 and then flows in the first path 122 in the circumferential direction of the fin assembly 61. The liquid coolant that has reached the downstream end of the first path 122 is guided into the first coolant path 163 of the second path 161 through the third path 124 and the coolant inlet port 167. The liquid coolant further flows into the second coolant path 164 via the communication path 165.

The liquid coolant guided into the first and second coolant paths 163 and 164 passes through the heat diffusing members 169 and 170, respectively. Heat is thereby transferred from the liquid coolant to the heat diffusing members 169 and 170. The heat is further transferred to the base 144 and the outer cover 146 through the heat diffusing members 169 and 170. Furthermore, most of the heat propagates from the outer circumference of the base 144 to the fin assembly 61.

In the seventh embodiment, the liquid coolant guided to the radiator 32 flows in the first path 122 along the fin assembly 61 and then flows in the first and second coolant paths 163 and 164 of the second path 161. The fin assembly 61 therefore has a flow path for the liquid coolant, which is twice as long as in the fist embodiment. As a result, heat can propagate to each heat radiating fin 80 from two paths, i.e., the first path 122 and the second path 161.

Therefore, as the surface temperature of each heat radiating fin 80 rises, the heat more easily propagates to the corners of the heat radiating fin 80. Heat can be efficiently radiated from the surface of each heat radiating fin 80. This increases the heat radiating performance of the radiator 32.

Moreover, heat can be efficiently transmitted from the liquid coolant to the base 144 and the outer cover 146 through the heat diffusing members 169 and 170, because the liquid coolant flowing in the second path 161 passes along the heat diffusing members 169 and 170. As a result, heat exchange can be efficiently achieved for the liquid coolant flowing in the second path 161, enhancing the heat radiating performance of the radiator 32.

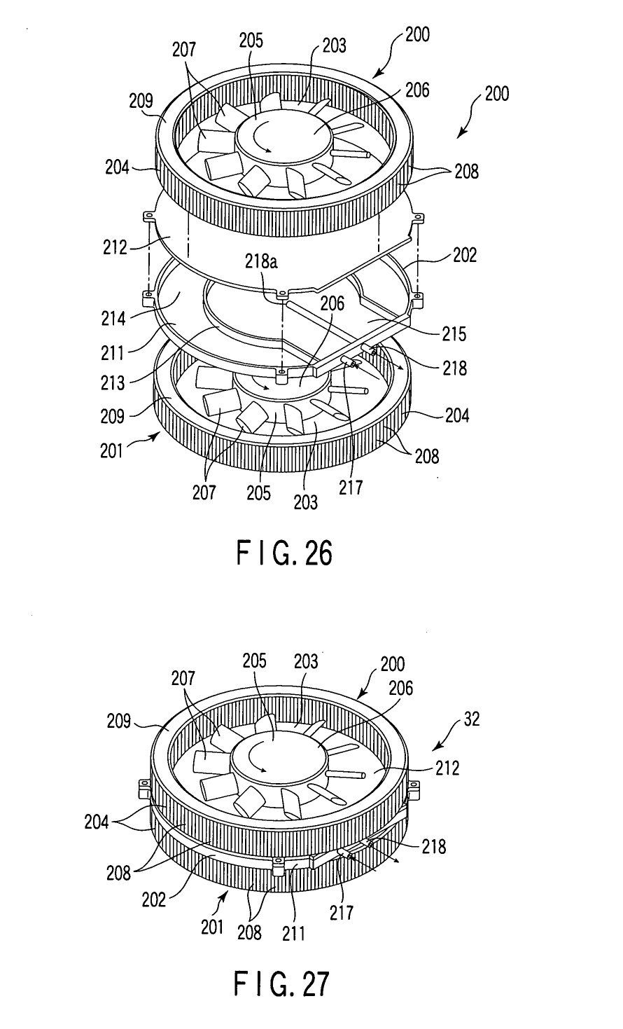

FIGS. 26 and 27 illustrate a radiator 32 according to an eighth embodiment of the present invention.

This radiator 32 comprises a pair of air-cooling units 200 and 201 and a passage 202. The air-cooling unit 200 and 201 are of the same configuration, each comprising an axial-flow fan 203 and a fin assembly 204 shaped like a ring and surrounding the fan 203.

The fan 203 has an impeller 205. The impeller 205 has a hub 206 and a plurality of vanes 207. The hub 206 has its center aligned with the axis of the impeller. The vanes 207 project from the hub 206 in the radial direction thereof. The vanes 207 incline to the axis of the impeller 205. When the impeller 205 is driven, air flows along the axis of the impeller 205.

The fin assembly 204 comprises a plurality of heat radiating fins 208 shaped like a flat plate and a connecting plate 209 shaped like a ring. The heat radiating fins 208 are arrange in the circumferential direction of the impeller 205, are spaced apart from one another and extend in radial direction from the axis of the impeller 205. The connecting plate 209 is soldered to the edge of each heat radiating fin 208, extending over any two adjacent fins 208. Hence, the heat radiating fins 208 are arranged at regular intervals, and any adjacent heat radiating fins 208 are coupled.

The passage 202 has a main body 211 and a top cover 212. The main body 211 and the top cover 212 are shaped like a disc, having an outside diameter that is almost the same as that of the fin assembly 204. The main body 211 and the top cover 211 define a closed space between them. The space is divided by a partition wall 213 into a heat transfer chamber 214 and a reservoir tank 215. The heat transfer chamber 214 curves in the form of an arc, extending in the circumferential direction of the fin assembly 204. The reservoir tank 215 is surrounded by the heat transfer chamber 214.

The main body 211 has an inlet pipe 217 and an outlet pipe 218. Liquid coolant flows in through the inlet pipe 217 and flows out through the outlet pipe 218. The inlet pipe 217 and the outlet pipe 218 are spaced apart and open to the interior of the reservoir tank 215. As shown in FIG. 26, the outlet pipe 218 extends deeper into the reservoir tank 215 than the inlet pipe 217. The outlet pipe 218 has a coolant inlet port 218a that lies in the middle part of the reservoir tank 215. The coolant inlet port 218a remains immersed in the liquid coolant stored in the reservoir tank 215, whichever position the radiator 32 takes.

The two air-cooling units 200 and 201 lie, with the passage 202 interposed between them. The fin assembly 204 of one air-cooling unit 200 is laid on the outer circumferential edge of the top cover 212 and is therefore thermally connected to the top cover 212. The impeller 205 of the fan 203, which is surrounded by the fin assembly 204, has its hub 206 supported on the center part of the upper surface of the top cover 212.

The fin assembly 204 of the other air-cooling unit 201 is laid on the outer circumferential edge of the lower surface of the main body 211 and is therefore thermally connected to the main body 211. The impeller 205 of the fan 203, which is surrounded by the fin assembly 204, has its hub 206 supported on the center part of the lower surface of the main body 211.

When the impeller 205 is driven, air flows along the axis of the impeller 205. The air is applied to the upper surface of the top cover 212 and to the lower surface of the main body 211. The air then flows in the radial direction of the impeller 205. Thus, the direction of air flow changes. The air is cooling air, which flows toward the heat radiating fins 208 of the fin assemblies 204.

In this configuration, the liquid coolant heat is forced into the reservoir tank 215 through the inlet pipe 217. The liquid coolant may contain bubbles. In this case, the bubbles are removed from the coolant in the reservoir tank 215. The coolant inlet port 218a of the outlet pipe 218 remains immersed in the liquid coolant stored in the reservoir tank 215. Therefore, only the liquid coolant is drawn into the outlet pipe 218.

In the present embodiment, the inlet pipe 217 and the outlet pipe 218 constitute a gas-liquid separating mechanism that removes bubbles from the liquid coolant. The gas-liquid separating mechanism is integral with the reservoir tank 215.

The heat of the liquid coolant temporarily stored in the reservoir tank 215 is transmitted to one fin assembly 204 from the lower surface of the main body 211 and to the other fin assembly 204 from the upper surface of the top cover 212. The heat transmitted to the fin assemblies 204 is radiated from the radiator 32 as the cooling air flows through the gaps between the heat radiating fins 208.

In the eighth embodiment, the passage 202 is provided between the air-cooling units 200 and 201. The heat of the liquid coolant temporarily stored in the reservoir tank 215 can therefore be transferred to the two fin assemblies 204. Thus, the heat radiating area of the radiator 32 is twice as large.

Further, the cooling air is applied to the main body 211 and top cover 212 of the passage 202 when the impeller 205 is driven. The liquid coolant temporarily stored in the reservoir tank 215 can therefore be cooled at high efficiency. This and the heat radiating area twice as large enhance the heat radiating performance of the radiator 32.

In the third to eighth embodiments described above, the vanes of the impeller may be inclined into alignment with the direction in which air flows from the distal end of each vane, in the same manner as in the second embodiment.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A cooling apparatus comprising:
an outlet port through which cooling air is applied in a radial direction;
a plurality of heat radiating fins which are arranged at intervals and which surround the outlet port, each having a first edge and a second edge located opposite to the first edge;
a first path which has a downstream end, which extends in the direction the heat radiating fins are arranged, which is thermally connected to the second edge of each heat radiating fin and in which liquid coolant flows;
a second path which has an upstream end, which extends in the direction the heat radiating fins are arranged, which is thermally connected to the first edge of each heat radiating fin and in which the liquid coolant flows; and
a third path which connects the downstream end of the first path and the upstream end of the second path and in which the liquid coolant flows.

2. A cooling apparatus comprising:
a heat receiving portion which is thermally connected to a heat generating component;
a heat radiating portion which radiates heat of the heat generating component; and
a circulation path which circulates liquid coolant between the heat receiving portion and the heat radiating portion,
said heat radiating portion including:
an outlet port through which cooling air is applied in a radial direction;
a plurality of heat radiating fins which are arranged at intervals and which surround the outlet port; and
a passage which extends in a direction the heat radiating fins are arranged, which is thermally connected to the heat radiating fins and in which liquid coolant heated in the heat receiving portion flows.

3. The cooling apparatus according to claim 2, wherein the passage includes a flatten pipe, and each of the heat radiating fins has an edge having a recess in which the flatten pipe is fitted.

4. The cooling apparatus according to claim 2, wherein the heat receiving portion includes a pump which applies a pressure to the liquid coolant, forcing out the liquid coolant.

5. A cooling apparatus comprising:
a heat receiving portion which is thermally connected to a heat generating component;
a heat radiating portion which radiates heat of the heat generating component;
a circulation path which circulates liquid coolant between the heat receiving portion and the heat radiating portion; and
a fan which has an impeller having a plurality of vanes and which is configured to apply cooling air in a radial direction, from a distal end of each vane toward the heat radiating portion, when the impeller is rotated,
said heat radiating portion including:
a plurality of heat radiating fins which are arranged at intervals and which surround the impeller of the fan; and
a passage which extends in a direction the heat radiating fins are arranged, which is thermally connected to the heat radiating fins and in which liquid coolant heated in the heat receiving portion is guided,
said heat radiating fins incline to a tangent to the direction in which the impeller rotates, with respect to a locus of the distal end of each vane of the impeller.

6. The cooling apparatus according to claim 5, wherein the passage includes a flatten pipe, and each of the heat radiating fins has an edge having a recess in which the flatten pipe is fitted.

7. The cooling apparatus according to claim 5, wherein the impeller has a hub aligned with an axis of the impeller, the vanes project from the hub in radial direction, and the heat radiating fins extend substantially at right angles to the direction in which the vanes project.

8. The cooling apparatus according to claim 5, wherein the heat receiving portion includes a pump which applies a pressure to the liquid coolant, forcing out the liquid coolant.
